(19) United States
(12) Patent Application Publication
(10) Pub. No.: US 2009/0178343 A1
(43) Pub. Date: Jul. 16, 2009

(54) WEATHERSTRIP INCORPORATING PINCH SENSOR, NEW PINCH SENSORS, AND ASSOCIATED METHODS

(76) Inventors: John Zimmer, Canton, MI (US); Eric Drozd, Farmington Hills, MI (US); Sean Scott, Walled Lake, MI (US)

Correspondence Address: Fay Sharpe LLP, 1228 Euclid Avenue, 5th Floor, The Halle Building, Cleveland, OH, 44115, US

(21) Appl. No.: 12/064,054

(22) PCT Filed: Aug. 17, 2006
(86) PCT No.: PCT/US06/32144

§ 371 Date: Aug. 28, 2008

Related U.S. Application Data
(60) Provisional application No. 60/709,187, filed on Aug. 18, 2005.

(51) Int. Cl. G01R 27/26; E06B 3/00; E06B 7/16

(52) U.S. Cl. 49/475.1; 49/506; 324/661

(57) ABSTRACT

A weatherstrip such as a glass run incorporates an associated anti-entrapment sensor. The glass run includes an elastomeric material having first and second legs interconnected by a base wall that together receive an associated automotive window peripheral edge and a recess formed in the elastomeric material dimensioned to receive the associated anti-entrapment sensor therein. The recess has a substantially T-shaped cross-sectional cavity in one embodiment and the pinch sensor has a substantially T-shaped cross-sectional conformation dimensioned for mating receipt in the T-shaped cavity. Facing, first and second flexible sidewall portions flex for ease of insertion and retention of the pinch sensor in the cavity. A fusible layer secures the weatherstrip and pinch sensor after assembly thereof. Preferably, the weatherstrip is formed from multiple materials, one of which is a low friction material.

### BACKGROUND OF THE INVENTION

This application claims the priority benefit of U.S. provisional application Ser. No. 60/709,187, filed 18 Aug. 2005, the subject matter of which is incorporated herein by reference.

This application relates to a weatherstrip, e.g. a glass run assembly or inner garnish assembly, and more particularly to a weatherstrip incorporating a new pinch sensor or anti-entrapment sensor, a known pinch sensor, and associated methods of manufacturing same. An exemplary embodiment finds particular application in vehicles such as an automobile that includes powered windows having an “express up” or “auto-up” feature.

Preferably, the pinch sensor is a capacitance sensor. Capacitance-type pinch sensors are known, for example, various embodiments of which are disclosed in US published application US 2005/0092097 A1, published May 5, 2005. As taught for example in the above-noted published application, one embodiment of the pinch sensor includes first and second electrical conductors that are separated by a compressible dielectric material. The three components are encased in an outer jacket such as a non-conductive elastomer. In response to an object touching or coming into proximate contact with the outer jacket, the separation distance between the electrical conductors is altered thereby causing a change in capacitance, or the capacitance of the sensor changes even without actual contact. The detected change in capacitance is monitored by a controller which can prevent further movement of a translating component such as a window door, moonroof, etc., for example, or reverse direction of the moving component.

By locating a pinch sensor at strategic locations adjacent an automotive vehicle window, for example, the controller can terminate express-up operation of the window or reverse the window movement (i.e., lower the window) to a predetermined position. One perceived drawback associated with known arrangements is that the sensor is visibly apparent when mounted on the weatherstrip. This detracts from the aesthetics of the vehicle and also distracts the driver and/or vehicle passengers due to the abnormal outward extension of the pinch sensor from the weatherstrip. It is believed that known arrangements incur additional cost to the manufacture of the weatherstrip by attaching the pinch sensor to commercially available weatherstrips rather than advantageously integrating the pinch sensor into the design, aesthetics, and manufacture of the weatherstrip prior to incorporation into a vehicle in an economical, efficient manner.

Consequently, a need exists to address these deficiencies in a manner that is effective, cost-justified, and easy to manufacture.

### SUMMARY OF THE INVENTION

A method of forming a weatherstrip includes forming an elastomeric or plastic material, providing a recess along a surface of the extruded material, and feeding a sensor strip into the extruded material recess.

A pinch sensor for an automotive vehicle includes a flat, first braided electrically conductive member, and a flat, second braided electrically conductive member spaced from the first braided material. A compressible dielectric layer is interposed between the first and second braided members and a polymeric housing encases the first and second braided members and the dielectric layer.

### BRIEF DESCRIPTION OF THE DRAWINGS

FIG. 1 is a body side view of a supported glass run incorporating a pinch sensor.

FIG. 2 is a cross-section view taken generally along the lines 2-2 of FIG. 1.

FIG. 3 is a body side view of an unsupported glass run assembly used in a C-channel door construction.

FIG. 4 is a cross-sectional view taken generally along the lines 4-4 of FIG. 3.

FIG. 5 is a cross-sectional view taken generally along the lines 5-5 of FIG. 3.

FIG. 6 is a cross-sectional view taken generally along the lines 6-6 of FIG. 3.

FIG. 7 is an enlarged cross-sectional view of a glass run incorporating a preferred configuration of pinch sensor.

FIG. 8 is an enlarged cross-section of the pinch sensor shown in FIG. 7.

FIG. 9 is a body side view of an interior garnish assembly incorporating a pinch sensor.

FIG. 10 is a cross-sectional view generally along the lines 10-10 of FIG. 9.

FIG. 11 is a body side view of an interior garnish assembly in a C-channel door construction incorporating a pinch sensor.

FIG. 12 is a cross-sectional view taken generally along the lines 12-12 of FIG. 11.

FIG. 13 is a cross-sectional view taken generally along the lines 13-13 of FIG. 11.

### DETAILED DESCRIPTION OF THE INVENTION

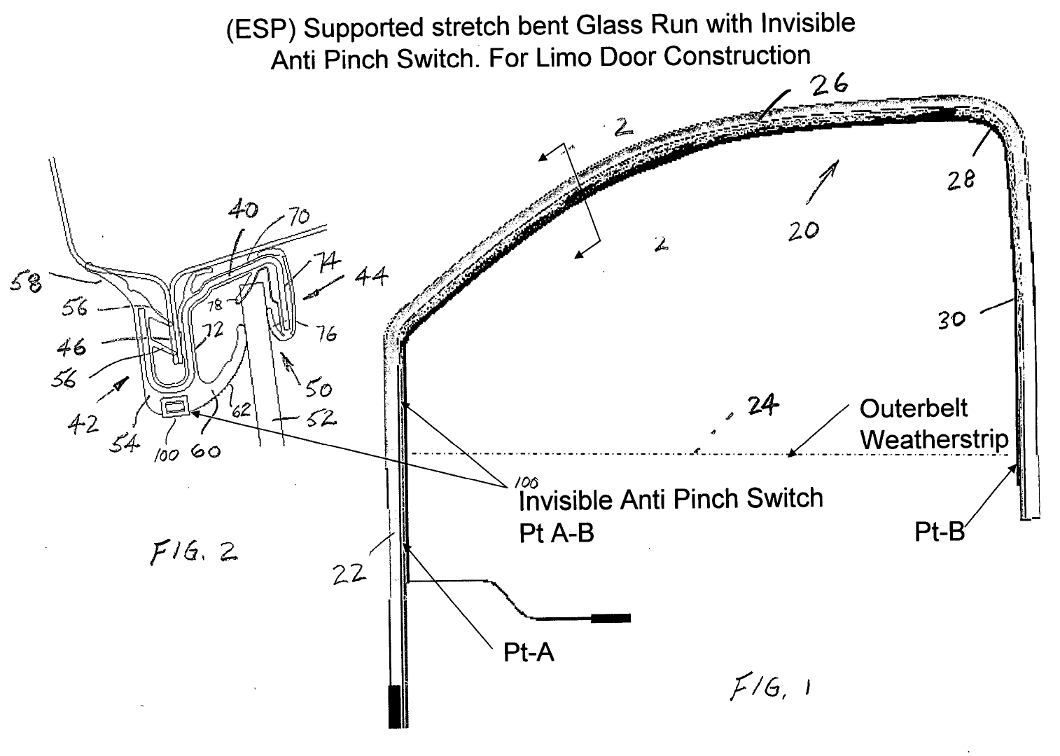

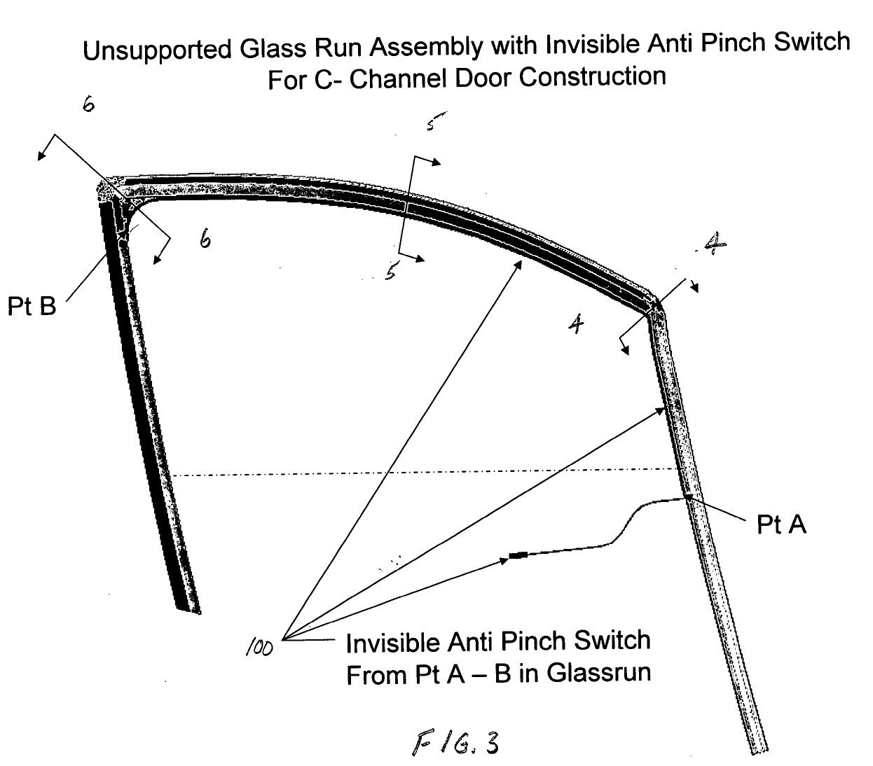

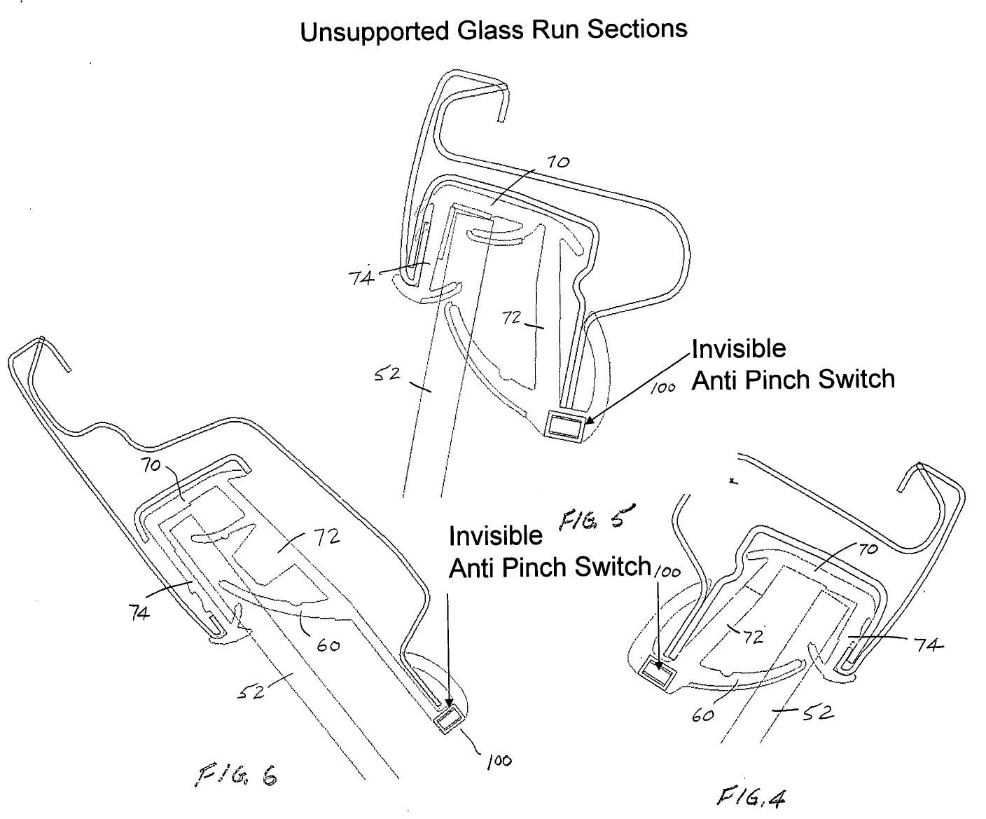

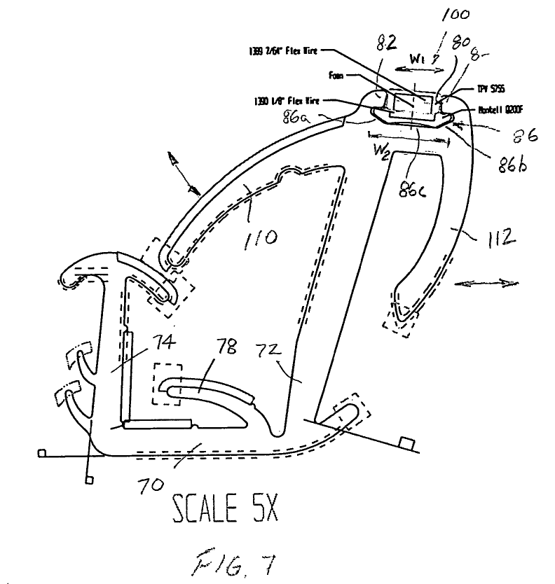

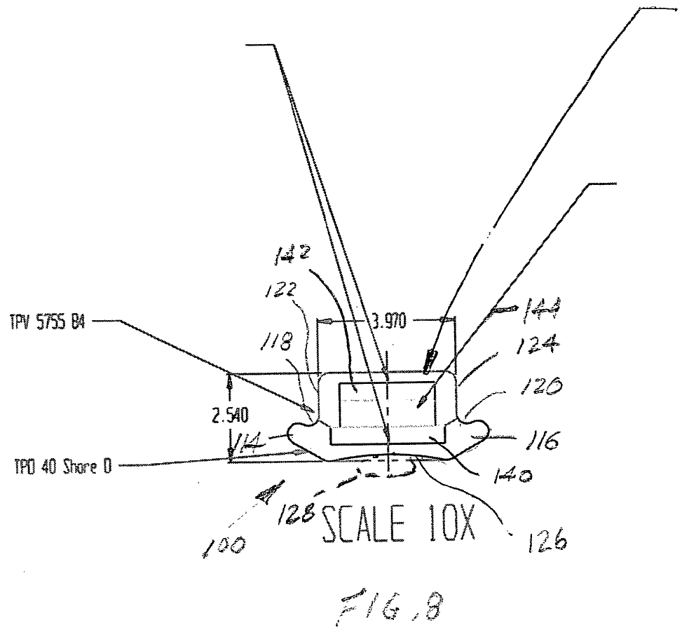

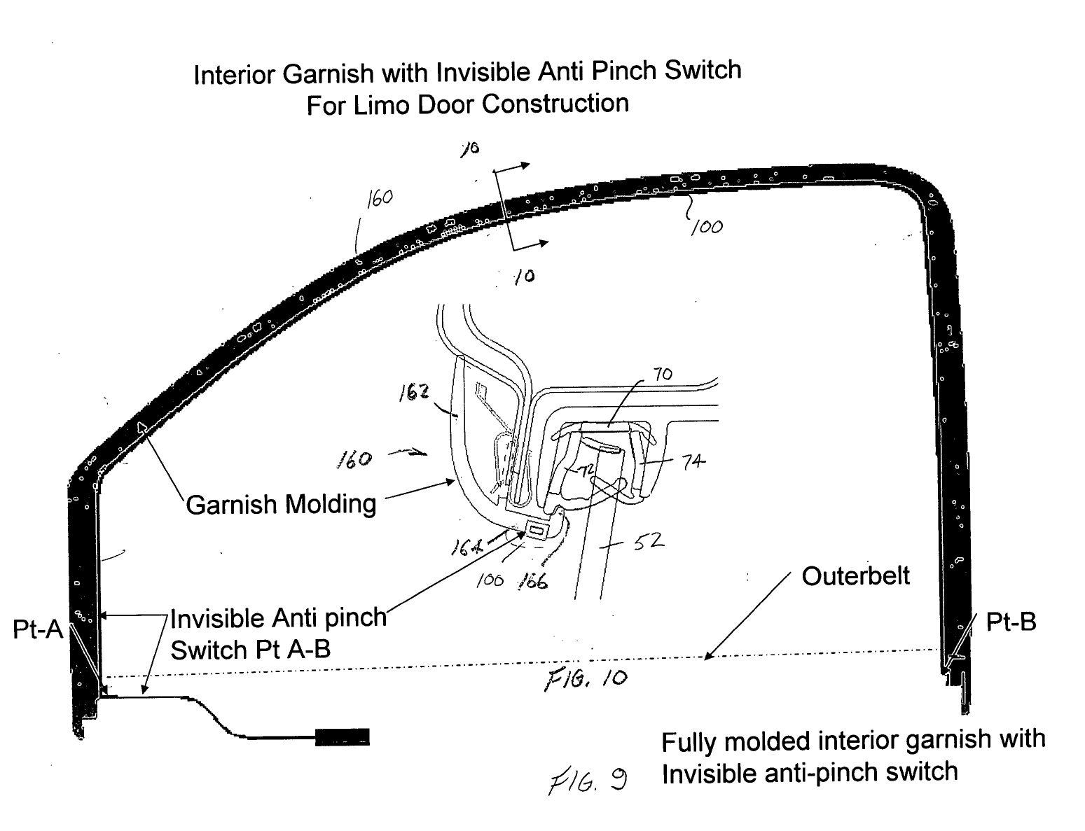

Turning initially to FIGS. 1 and 2, a supported glass run assembly 20 is shown as extending along a vehicle door (not shown). A pillar portion 22 of the glass run assembly extends from beneath belt line 24 and transitions into header portion 26, a the cross-sectional view of which is shown in FIG. 2. At region 28, the glass run is tightly curved or bent where the glass run assembly merges from the header portion into B pillar portion 30.

As best illustrated in FIG. 2, the glass run includes a support member or core such as a rigid plastic or metal core 40. Here, the core is defined by contiguous U-shaped portions 42, 44 that are reverse bent relative to one another. The first U-shaped portion 42 is dimensioned for receipt about a flange 46 of the vehicle and adapted to tightly grip the flange as will be described below. The second U-shaped portion 44 provides support for the inverted U-shaped channel 50 that receives window 52 of the vehicle.

More particularly, the core is at least partially or preferably completely encapsulated in a thermoplastic or elastomeric member 54 such as EPDM, rubber, plastic, etc. In the embodiment of FIGS. 1 and 2, this material is generally referenced as an elastomer, although it will be appreciated that other materials may be used with equal success without departing from the scope and intent of the invention. The elastomer 54 is formed around the core, for example, molded or extruded thereabout. The elastomeric weatherstrip is profiled for gripping receipt of the vehicle flange and dimensioned to receive a peripheral edge of the window. Gripping flanges 56 (two shown in FIG. 2) extend outwardly from the profile and sealingly secure the glass run assembly to the vehicle flange. An installation tool (not shown) may assist in mounting the U-shaped portion 42 and gripping flanges 56 to the vehicle flange to provide a secure interconnection to the vehicle in a manner well known in the art.

Lip 58 extends from the portion 42 and engages the vehicle along an edge to provide a smooth, aesthetically pleasing interface with the vehicle. A second lip or seal lip 60 extends in an opposite direction and flexibly engages an inner surface of the window. Preferably, the surface of the seal lip 60 includes a low friction layer or material 62 that allows the window to easily slide relative to the weatherstrip. As will be appreciated, the low friction material may be coextruded on those portions of the weatherstrip that are adapted for engagement with the window.

The second U-shaped portion of the weatherstrip includes a base 70 that interconnects first and second legs 72, 74 to form the channel 50 that receives window edge. The seal lip 60 extends inwardly into the channel for sliding engagement with the inner surface of the window and, similarly, seal lip 76 slidably engages the outer surface of the window. Lip 78 extending from the base 70 may also be provided in the channel to engage the peripheral edge of the window when received in the channel.

FIGS. 3-6 illustrate an unsupported glass run assembly, i.e., one without a rigid core. Because the glass run is unsupported, the vehicle includes C-shaped portions into which the glass run is inserted and secured for example with fasteners (not shown). However, it will be understood that the weatherstrip functions in a similar manner, that is, guiding and supporting the peripheral edge of the window as the window is raised and lowered. Like numerals refer to like elements and the structure and function is substantially similar to that described above with the other embodiment.

FIGS. 7 and 8 more particularly illustrate the pinch sensor and modifications thereto that allow the sensor to be securely installed in the weatherstrip. Although FIG. 7 shows an unsupported glass run, the details of the pinch sensor and incorporation into the weatherstrip are also equally applicable to the supported glass run version. Specifically, the weatherstrip is formed (molded or extruded) with a T-shaped cavity 80 generally defined by substantially parallel, first and second sidewalls 82, 84 spaced by dimension W1, and a contoured bottom groove 86 that has a width W2 greater than the width W1 between the sidewalls. The groove has undercut portions 88, 90 so that pinch sensor 100 is positively and securely retained in the weatherstrip.

The contoured bottom groove 86 includes inclined outer regions 86a, 86b and a generally planar interconnecting portion 86c. As will be appreciated from FIG. 7, the sidewalls 82, 84 provide a locking function with the pinch sensor. Particularly, the sidewalls are advantageously associated with outwardly extending lip portions of the glass run. For example, the first sidewall 82 is associated with lip 110 of the glass run. Likewise, lip 112 extends from the second sidewall portion 84. This arrangement is helpful in installation of the pinch sensor 100 into the cavity 80. Specifically, lips 110, 112 act as lever arms so that the sidewalls 82, 84 are spread further apart and allow easy access to the cavity 80 when the lips are brought toward one another as illustrated by the reference arrows. On the other hand, the sidewalls 82, 84 are urged toward one another when the lips 110, 112 are urged in the opposite direction, i.e., away from one another. As perhaps best illustrated in FIGS. 4 and 5, this allows the pinch sensor to be inserted into the cavity after the glass run has been formed, and prior to insertion into the mating cavity that receives the unsupported glass run. Once mounted in the vehicle, the lip 112, in particular, is urged outwardly and thus securely retains the pinch sensor within the cavity. The sidewalls 82, 84 prevent the T-shaped pinch sensor from being inadvertently removed from the cavity.

As more particularly shown in FIG. 8, the pinch sensor 100 is a composite structure. It has a mating, generally T-shape defined by first and second outwardly extending legs or flanges 114, 116 that extend outwardly from opposite edges along the longitudinal length thereof for receipt in the cavity. Undercut regions 118, 120 provide further retention benefit and receive lower edges of the first and second sidewalls 82, 84. These sidewalls abuttingly engage against longitudinally extending edges 122, 124 of the pinch sensor.

A lower surface of the pinch sensor may also include a recessed region 126 that forms a longitudinally extending cavity with the lower wall 86c of the glass run pinch sensor groove. The cavity 126 may incorporate a heat-fusible material, or adhesive, represented by dotted line reference numeral 128 that would subsequently lock the pinch sensor in place relative to the weatherstrip.

In addition, it has been found that use of a flat braid for the electrically conductive components are best suited for providing flexibility to the pinch sensor in the weatherstrip. For example, in tight bend regions such as region 28 of FIG. 1, it is important that the weatherstrip with the incorporated pinch sensor be sufficiently flexible so as not to adversely impact on electrical conductivity of the pinch sensor. The braided arrangement assures that there are numerous conductive paths rather that using a single wire, which if broken anywhere along its length, loses its electrical conductivity properties. The braids, on the other hand, have multiple conductive paths and are inexpensive due to the wide range of use of braided wire in areas other than pinch sensors. The electrically conductive braids 140, 142 are separated by a foam material 144 that is electrically non-conductive. For example, a flexible polyurethane foam that includes a polyester film laminate on one side that is particularly helpful for operation of the capacitance sensor.

The electrically conductive members and the foam material are encapsulated in suitable electrically inert material, such as a TPO, TPV, or polyethylene. If molded, the temperature can be maintained sufficiently low so as not to destroy the individual components of the sensor. If extruded, on the other hand, the pinch sensor may be formed from multiple materials such as a TPO in the lower portion, e.g., flanges 114, 116 and base wall 126, while the upper portion defined by sidewalls 122, 124 may be formed from a TPV. Inclusion of a low-density polyethylene 128 between the TPO of the base portion of the pinch sensor will allow the TPO to bond with the EPDM of the remainder of the weatherseal.

If molded, the pinch sensor is positioned in place in the mold and the polypropylene formed therearound to interconnect the garnish, inner belt, and switch as an integral molded assembly.

It has been found in some instances, that use of the braided material can unfortunately take a set, i.e., deform, if undesired force is applied to the pinch sensor. By way of example only, if a vehicle driver contacts the pinch sensor with a piece of lumber, the pinch sensor may take a permanent set which is aesthetically undesirable, even though the switch may still operate properly. Thus, use of a lanced or stamped metal component for one of the electrically conductive members, i.e., the outer electrically conductive member 142 could be used in conjunction with the inner braided conducting member 140. This would reduce the overall costs since the lanced or stamped version is substantially more expensive than the braided version.

It is also desirable that the pinch sensor be separately assembled to the glass run, for example, so that the glass run can be cut to length or notched. In such an instance, the pinch sensor is applied only over a portion of the length. Where notching or subsequent cutting is required, it is desirable if the pinch sensor not be in place during these operations. Thus, the weatherstrip and pinch sensor are separately manufactured and then assembled prior to being shipped to the customer for installation on a vehicle.

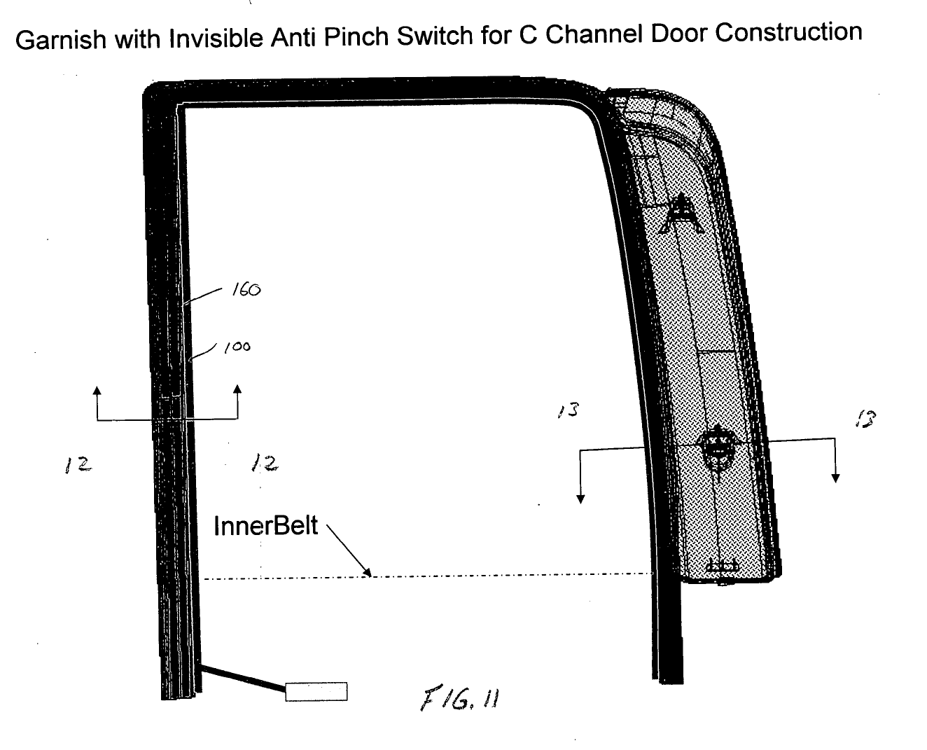

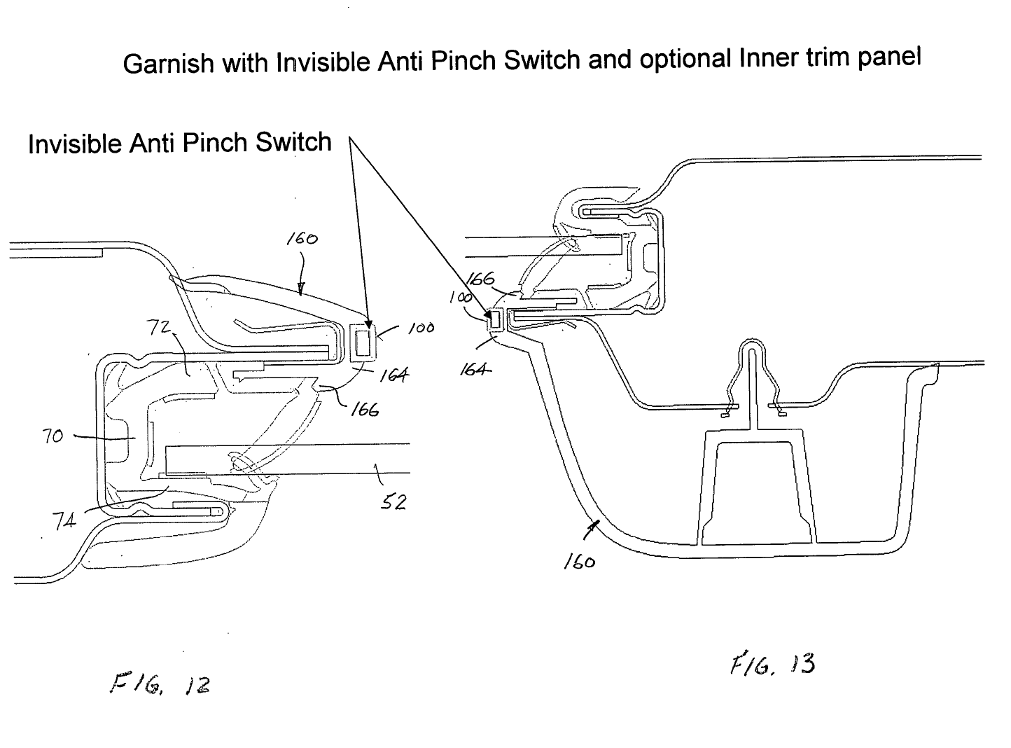

FIGS. 9 and 10 illustrate a cooperation of a pinch sensor into an inner garnish of a vehicle. The garnish molding, for example the type shown and described in commonly owned, co-pending application PCT/US2005/042159, filed 18 Nov. 2005, is formed about the inner perimeter of the window opening of a vehicle. Garnish molding 160 includes an enlarged molded lip 162 that covers the inner perimeter around the vehicle window. It also includes a lip 164 that extends over and lockingly engages at 166 with the glass run assembly. This arrangement seals the gap between the glass run and the inner garnish, and also advantageously provides a location for incorporating the pinch sensor adjacent the window of the vehicle. Although only schematically represented in FIGS. 9 and 10, and likewise FIGS. 11-13, it is apparent that the interconnection of the garnish with the glass run provides an ideal location for incorporating the pinch sensor into the assembly. The contoured arrangement (T-shape) between the pinch sensor and the remainder of the weatherstrip as described above with respect to FIGS. 7 and 8 is particularly suitable for this purpose also. On the other hand, since the garnish can be a molded component, it is also evident that the pinch sensor could be molded in place with the inner trim panel.

The invention has been described with reference to the preferred embodiment. Modifications and alterations will occur to others upon reading and understanding this specification. It is intended to include all such modifications and alterations in so far as they come within the scope of this description.

1. A method of forming a weatherstrip comprising:
forming an elastomeric or plastic material;
providing a recess along a surface of the extruded material; and
feeding a sensor strip into the extruded material recess.

2. The method of claim 1 wherein the recess providing step includes forming the recess in a generally U-shape.

3. The method of claim 2 wherein the recess providing step includes forming first and second legs that extend outwardly from and are interconnected by a base wall.

4. The method of claim 3 wherein the providing step includes angling the first and second legs toward one another as the legs extend outwardly from the base wall.

5. The method of claim 3 wherein the first leg joins the base wall at an intersection adjacent a seal lip of the weatherstrip such that deflecting the seal lip around the intersection pivots the first leg relative to the base wall.

6. The method of claim 5 wherein the second leg joins the base wall at a region adjacent a show surface of the weatherstrip such that deflecting the show surface around the region pivots the second leg relative to the base wall.

7. The method of claim 1 wherein the recess providing step is formed along only a portion of the length of the extruded material.

8. The method of claim 7 wherein the recess is provided along a header portion of the weatherstrip.

9. A glass run dimensioned incorporating an associated anti-entrapment sensor, the glass run comprising:
an elastomeric material having first and second legs interconnected by a base wall that together receive an associated automotive window peripheral edge; and
a recess formed in the elastomeric material dimensioned to receive the associated anti-entrapment sensor therein.

10. The glass run of claim 9 wherein the recess includes first and second sidewalls extending from a base portion.

11. The glass run of claim 10 wherein the first and second sidewalls angle inwardly toward one another as they extend from the base portion.

12. The glass run of claim 11 wherein the first and second sidewalls flex outwardly in response to forces imposed on the elastomeric material.

13. The glass run of claim 11 wherein the first sidewall merges into a show surface of the glass run.

14. The glass run of claim 13 wherein the second sidewall merges into a seal lip of the glass run.

15. The glass run of claim 15 wherein pressure exerted on the seal lip and show surface flexes the first and second sidewalls away from one another to facilitate insertion or removal of an associated anti-entrapment sensor.

16. A pinch sensor for an automotive vehicle comprising:
a flat, first braided electrically conductive member;
a flat, second braided electrically conductive member spaced from the first braided material;
a compressible dielectric layer interposed between the first and second braided members; and
a polymeric housing encasing the first and second braided members and the dielectric layer.

17. The sensor of claim 16 wherein the first and second braided members and the dielectric material are flexible without kinking in three perpendicular directions.

18. The pinch sensor of claim 16 wherein the first and second braided members are coextruded in an elastomeric or plastic housing with the dielectric layer therebetween.

19. The pinch sensor of claim 16 wherein the first and second braided members are molded in an elastomeric or plastic housing with the dielectric material therebetween.

20. A pinch sensor comprising:
a first, electrically conductive stamped or lanced copper member;
a second, electrically conductive stamped or lanced copper material spaced from the first material; and
a compressible dielectric layer interposed between the first and second materials.

21. The anti-entrapment sensor of claim 20 wherein the first and second braided materials are coextruded in an elastomeric housing with the dielectric layer therebetween.

22. A pinch sensor comprising:
a flat, braided first electrically conductive member;
a stamped or lanced second electrically conductive member disposed in spaced relation from the first electrically conductive member;
a compressible dielectric layer between the first and second conductive members; and
a polymeric housing encasing the first and second electrically conductive members and the dielectric layer.

23. A weatherstrip assembly for an associated automotive vehicle comprising:
an elongated weatherstrip having a flange portion with a substantially T-shaped cross-sectional cavity therein; and
a pinch sensor having a substantially T-shaped cross-sectional conformation dimensioned for mating receipt in the T-shaped cavity.

24. The weatherstrip assembly of claim 23 wherein the weatherstrip cavity is partially defined by facing, first and second flexible sidewall portions adapted to flex away from one another for ease of insertion of the pinch sensor into the cavity, and flex toward one another upon mounting of the weatherstrip assembly to an associated automotive vehicle for retaining the pinch sensor in the cavity.

25. The weatherstrip assembly of claim 23 wherein one of the weatherstrip and pinch sensor include a fusible layer for subsequently fusing the weatherstrip and pinch sensor after assembly thereof.

26. The weatherstrip assembly of claim 23 wherein the weatherstrip is comprised of multiple materials, one of which is a low friction material.

27. The weatherstrip assembly of claim 23 wherein the pinch sensor is formed from multiple materials.

28. The weatherstrip assembly of claim 27 includes a low-density polyethylene between a base portion of the pinch sensor and a remainder of the weatherseal to bond the components together.
